(19) United States
(12) Patent Application Publication
(10) Pub. No.: US 2015/0044388 A1
(43) Pub. Date: Feb. 12, 2015

(54) PLATING METHOD AND PRODUCT

(71) Applicant: CANON COMPONENTS, INC., Kodama-gun (JP)

(72) Inventor: Taisuke IWASHITA, Saitama-ken (JP)

(21) Appl. No.: 14/454,937

(22) Filed: Aug. 8, 2014

(30) Foreign Application Priority Data
Aug. 9, 2013 (JP) 2013167027
Jul. 31, 2014 (JP) 2014155786

(51) Int. Cl. C23C 18/20; H05K 1/03; C23C 18/16; H05K 3/18

(52) U.S. Cl. CPC C23C 18/204; H05K 3/184; H05K 3/185; H05K 1/0313; C23C 18/2053; C23C 18/1605; C23C 18/1641
USPC 427/553

(57) ABSTRACT

There is provided with a plating method. At least a portion of a surface of a resin product is irradiated with ultraviolet light. An alkali processing is performed on the resin product with an alkali solution. An electroless plating catalyst is applied to the portion of the surface of the resin product which is irradiated with the ultraviolet light in the irradiating. This applying includes processing the resin product with a solution containing a palladium complex having a positive electric charge at least at a part of the palladium complex. Electroless plating is performed on the resin product.

### BACKGROUND OF THE INVENTION

1. Field of the Invention

The present invention relates to a plating method and a product.

2. Description of the Related Art

A method of forming a metal film by performing plating on a resin product is known. For example, Japanese Patent Laid-Open No. 2008-094923 has disclosed a metal film formation method using surface modification by ultraviolet light. More specifically, the entire surface of a cycloolefin polymer material is first irradiated with an ultraviolet lamp, and surface modification necessary for electroless plating is performed after that by processing the cycloolefin polymer material with an alkali solution. Then, a metal film is formed by performing electroless plating on the modified cycloolefin polymer material.

As disclosed in Japanese Patent Laid-Open No. 2008-094923, a conditioning process, catalyst application process, and plating process are performed in the electroless plating method. In the conditioning process, a resin product is processed by, for example, a polymer as disclosed in Japanese Patent Laid-Open No. 2008-189831. This facilitates the adhesion of catalyst ions to the resin surface. After that, in the catalyst application process, the resin product is processed in a catalyst solution containing, for example, HCl-acidic palladium such as tetrachloropalladate. Consequently, the catalyst ions adhere to the resin surface. In addition, the catalyst is deposited by reducing the catalyst ions, and a plating metal is deposited on the deposited catalyst in the plating process, thereby forming a metal film.

International Publication No. 2007/066460 has disclosed a method of depositing a plating metal on a portion of a polyimide resin product. More specifically, a portion of the surface of the polyimide resin product is processed with an alkali solution, and an imide ring at the processed portion is opened, thereby modifying the polyimide resin product. After that, the polyimide resin product is processed with a catalyst solution containing a palladium complex, and the activation of the palladium catalyst and electroless plating are performed, thereby depositing a plating metal on the portion processed with the alkali solution. International Publication No. 2007/066460 describes that when using a basic amino acid complex of palladium as the palladium complex, a plating metal was deposited on only the portion processed with the alkali solution. On the other hand, International Publication No. 2007/066460 describes that when using an HCl-acidic palladium complex [PdCl₄]²⁻ as the palladium complex, no selectivity was obtained, that is, a plating metal was deposited on the entire polyimide resin product.

### SUMMARY OF THE INVENTION

According to an embodiment, a plating method comprises: irradiating at least a portion of a surface of a resin product with ultraviolet light; performing alkali processing on the resin product with an alkali solution; applying an electroless plating catalyst to the portion of the surface of the resin product which is irradiated with the ultraviolet light in the irradiating, the applying including processing the resin product with a solution containing a palladium complex having a positive electric charge at least at a part of the palladium complex; and performing electroless plating on the resin product.

According to another embodiment, a product comprises a resin product and a metal film, wherein the product is manufactured by a method comprising: irradiating at least a portion of a surface of a resin product with ultraviolet light; performing alkali processing on the resin product with an alkali solution; applying an electroless plating catalyst to the portion of the surface of the resin product which is irradiated with the ultraviolet light in the irradiating, the applying including processing the resin product with a solution containing a palladium complex having a positive electric charge at least at a part of the palladium complex; and performing electroless plating on the resin to form a metal film on the resin product.

Further features of the present invention will become apparent from the following description of exemplary embodiments (with reference to the attached drawings).

### BRIEF DESCRIPTION OF THE DRAWINGS

FIG. 1 is a schematic view of a resin product with a metal film obtained in Example 1.

FIG. 2 is a schematic view of a resin product with a metal film obtained in Comparative Example 1.

FIG. 3 is a schematic view of a resin product with a metal film obtained in Comparative Example 2.

FIG. 4 is a schematic view of an example of an ultraviolet irradiation apparatus to be used in an irradiation step.

FIG. 5 is a schematic view of an example of a mask to be used in the irradiation step.

### DESCRIPTION OF THE EMBODIMENTS

The method described in Japanese Patent Laid-Open No. 2008-094923 requires many processes as pre-processes of the plating process. This complicates the processing and poses the problem of a cost. In particular, according to studies made by the present inventor, when applying a catalyst by using a conventionally used HCl-acidic palladium complex solution, a plating metal was not sufficiently deposited unless the conditioning process was performed.

Also, when performing modification by irradiating only a portion of a resin product with ultraviolet light and depositing a plating metal on only the modified portion, it was not easy to reduce the number of steps while ensuring the selectivity. In particular, according to studies made by the present inventor, a plating metal could also be deposited on a portion not irradiated with ultraviolet light when using the method described in Japanese Patent Laid-Open No. 2008-094923.

On the other hand, it was not easy to modify only a desired portion in the method described in International Publication No. 2007/066460.

According to one embodiment of the present invention, the number of steps can be reduced when performing electroless plating on a resin product modified by ultraviolet light.

Embodiments applicable to the present invention will be explained below with reference to the accompanying drawings. Note that the scope of the present invention is not limited to the following embodiments. In one embodiment of the present invention, at least an irradiation step, alkali processing step, application step, and plating step are performed. Each step of this embodiment will be explained in detail below.

(Resin Product)

A resin product to be used in this embodiment is not particularly limited as long as the product has, on the surface, a resin material which can be modified such that a plating metal is selectively deposited on an ultraviolet-irradiated portion. An example of the resin material is a cycloolefin polymer material, polystyrene material, or polyethylene terephthalate material. In one embodiment, the resin material is a carbon polymer formed by carbon atoms and hydrogen atoms, and the carbon polymer includes a cycloolefin polymer material. The cycloolefin polymer material can be, for example, a polymer having a repeating unit indicated by formula (I) below:

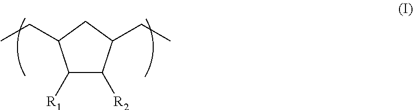

In the above formula, R₁ and R₂ each independently represent a hydrogen atom or a hydrocarbon group having 1 to 12 carbon atoms. This hydrocarbon group includes, for example, an alkyl group having 1 to 12 carbon atoms. Examples of the alkyl group are a methyl group, ethyl group, and cyclohexyl group. In one embodiment, each of R₁ and R₂ is a divalent hydrocarbon group having 1 to 12 carbon atoms. This divalent hydrocarbon group includes, for example, a divalent alkyl group having 1 to 12 carbon atoms. Examples of the divalent alkyl group are a 1,3-propanediyl group, 1,3-cyclopentanediyl group, and 5-methylcyclopentane-1,3-diyl group. An example of the polymer is a polymer having one of repeating units A to E below.

| | A 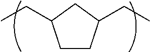 | B 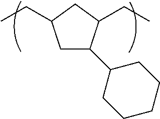 | C 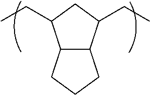 | D 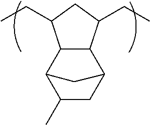 | E 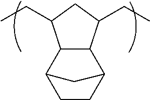 |
|---|---|---|---|---|---|
| Prop- | Crystalline | Amorphous | Amorphous | Amorphous | Amorphous |
| erties | | | | | |
| Trans- | Opaque | Transparent | Transparent | Transparent | Transparent |
| paren- | | | | | |
| cy | | | | | |
| Tq/ | 134 | 86 | 95 | 150 | 162 |
| ° C. | | | | | |

The cycloolefin polymer material may also contain a plurality of repeating units. Also, the resin material may contain a plurality of cycloolefin polymer materials. The glass transition temperature (Tg) can be adjusted by mixing a plurality of cycloolefin polymers having different Tg's. The cycloolefin polymer material to be used in one embodiment is obtained by mixing cycloolefin polymer materials having any of the above-mentioned repeating units A to E, and its Tg is 160° C. This cycloolefin polymer material is mainly formed by a cycloolefin polymer material having the above-mentioned repeating unit E.

The cycloolefin polymer material indicated by the above formula is formed by carbon atoms and hydrogen atoms. The cycloolefin polymer material according to one embodiment is a chemically highly stable substance. The weight-average molecular weight of the cycloolefin polymer material is not particularly limited, and is 1×10⁴ (inclusive) to 1×10⁶ (inclusive) in one embodiment.

In this embodiment, the resin product is a substrate formed into a planar shape. However, the resin product can have an arbitrary three-dimensional shape. Also, the resin product need not be formed by a resin alone. That is, in one embodiment, the resin product is a composite material having a coated structure obtained by coating the surface of another material with a resin material. A practical example of this composite material is a material obtained by coating the surface of a metal material with a resin material. The shape of this metal material is not particularly limited, and can be a substrate-like shape or more complicated three-dimensional shape.

(Irradiation Step)

In the irradiation step, at least a portion of the surface of the resin product is irradiated with ultraviolet light. More specifically, the resin product is modified when irradiated with ultraviolet light in an ambient containing at least one of oxygen or ozone. For example, a mask having an ultraviolet transmitting portion corresponding to the shape of a portion to be irradiated with ultraviolet light on the surface of the resin product is placed on the resin product, and ultraviolet light is emitted through this mask. Consequently, the desired portion can selectively be modified.

In one embodiment, ultraviolet light having a wavelength of 243 nm or less is emitted. This ultraviolet light having a wavelength of 243 nm or less decomposes oxygen molecules in the ambient, thereby generating ozone. The ozone thus generated reacts with a resin such as a cycloolefin polymer material similarly activated by the ultraviolet light, thereby forming a hydrophilic group such as a carboxyl group on the resin product surface. More specifically, active oxygen generated in the process of decomposing ozone reacts with the resin on the surface of which the molecular chain is broken by the ultraviolet light, thereby forming a hydrophilic group. The resin product surface is presumably thus modified to facilitate adsorbing catalyst ions.

For example, when ultraviolet light equal to or lower than a specific wavelength capable of decomposing oxygen is emitted in an oxygen-containing ambient, oxygen in the ambient is decomposed, and ozone is generated. In addition, active oxygen is generated in an ozone decomposing process.

The energy of a photon having a specific wavelength can be represented by:

E=Nhc/λ(KJ·mol⁻¹)

N=6.022×10²³ mol⁻² (Avogadro's number)

h=6.626×10⁻³⁷ KJ·s (Planck's constant)

c=2.988×10⁸ m·s⁻² (light velocity)

λ=wavelength (nm) of light

The bonding energy of an oxygen molecule is 490.4 KJ·mol⁻¹. When this bonding energy is converted into the wavelength of light from the photon energy equation, the wavelength is about 243 nm. This indicates that oxygen molecules in the ambient absorb ultraviolet light having a wavelength of 243 nm or less, and decompose. As a consequence, ozone O₃ is generated. In addition, active oxygen is generated in an ozone decomposing process. In this state, if ultraviolet light having a wavelength of 310 nm or less exists, ozone is efficiently decomposed, and active oxygen is generated. Furthermore, ultraviolet light having a wavelength of 254 nm most efficiently decomposes ozone.

O₂+hν(243 nm or less)→O(3P)+O(3P)

O₂+O(3P)→O₃ (ozone)

O₃+hν(310 nm or less)→O₂+O(1D) (active oxygen)

O(3P): ground-state oxygen atom

O(1D): excited oxygen atom (active oxygen)

Ultraviolet light as described above can be emitted by using an ultraviolet lamp which continuously radiates ultraviolet light. Examples of the ultraviolet lamp are a low-pressure mercury lamp and excimer lamp. The low-pressure mercury lamp can emit ultraviolet light having wavelengths of 185 and 254 nm. As reference, examples of the excimer lamp usable in the atmosphere will be presented below. An Xe₂ excimer lamp is generally used as the excimer lamp.

Xe₂ excimer lamp: wavelength=172 nm

KrBr excimer lamp: wavelength=206 nm

KrCl excimer lamp: wavelength=222 nm

When irradiating the resin product with the ultraviolet light, the ultraviolet irradiation is controlled so that the irradiation amount has a desired value. The irradiation amount can be controlled by changing the irradiation time. The irradiation amount can also be controlled by changing, for example, the output of the ultraviolet lamp, the number of ultraviolet lamps, or the irradiation distance.

In one embodiment, to sufficiently deposit a plating metal within a shorter time, the ultraviolet irradiation amount in the irradiation step is 400 (inclusive) to 810 (inclusive) mJ/cm² at a wavelength of 185 nm. For example, in one embodiment in which the ultraviolet irradiation intensity is 1.35 mW/cm² at a wavelength of 185 nm, the ultraviolet irradiation time is 5 (inclusive) to 10 (inclusive) min. In the following description, the ultraviolet irradiation amount and irradiation intensity indicate values at a wavelength of 185 nm unless otherwise specified.

The plating metal deposition conditions can change in accordance with, for example, the type of plating solution, the type of substrate, the degree of contamination on the substrate surface, the concentration, temperature, pH, and deterioration with time of the plating solution, and the output fluctuation of the ultraviolet lamp. Accordingly, the irradiation amount from the ultraviolet lamp need only be determined so that a plating metal is selectively deposited on only the portion irradiated with the ultraviolet light.

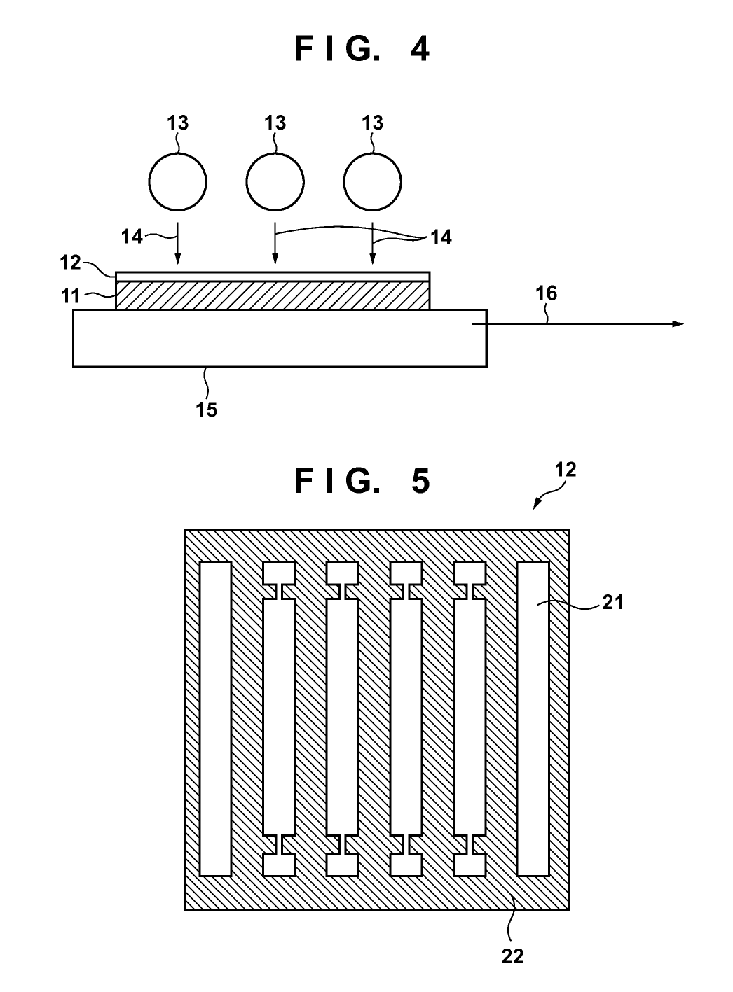

An example of an ultraviolet irradiation apparatus to be used in the irradiation step will be explained below with reference to a schematic configuration view of FIG. 4. Ultraviolet lamps 13 emit ultraviolet light 14 having a predetermined energy. The ultraviolet light 14 irradiates a resin product 11 through a mask 12 arranged on the resin product 11. FIG. 5 is a schematic view of a metal mask as an example of the mask 12. The mask 12 includes ultraviolet transmitting portions 21, and a portion 22 which does not transmit ultraviolet light. The shapes, that is, the positions and sizes of the ultraviolet transmitting portions 21 correspond to the shapes, that is, the positions and sizes of desired portions to be plated of the surface of the resin product 11. Therefore, the desired portions to be plated of the surface of the resin product 11 are modified when irradiated with the ultraviolet light 14 transmitted through the ultraviolet transmitting portions 21. The mask 12 shown in FIG. 5 is a metal mask, the ultraviolet transmitting portions 21 are openings, and the portion 22 which does not transmit ultraviolet light is made of a metal. However, the mask 12 is not limited to a metal mask like this. For example, the mask 12 may also be a quartz-chromium mask. In this case, the ultraviolet transmitting portions 21 are portions where no chromium film is formed on quartz, and the portion 22 which does not transmit ultraviolet light is a portion where a chromium film is formed on quartz.

In one embodiment as described above, the surface of the resin product 11 is modified by using ozone and ultraviolet light. In this embodiment, oxygen exists between the ultraviolet lamps 13 and resin product 11, and the resin product 11 to be modified contacts with oxygen. In one embodiment, the resin product 11 is fixed immediately below the ultraviolet lamps 13, and irradiated with the ultraviolet light 14. In another embodiment, the resin product 11 is fixed on a conveyance stage 15, and irradiated with the ultraviolet light 14 while the conveyance stage 15 is moved in a conveyance direction 16 at a desired velocity. In still another embodiment, the resin product 11 is irradiated with the ultraviolet light 14 while the resin product 11 itself is moved at an arbitrary velocity.

(Alkali Processing Step)

In this embodiment, the alkali processing is further performed after the irradiation step. When the alkali processing is performed on the resin product irradiated with the ultraviolet light, the portion irradiated with the ultraviolet light is further modified, and this further facilitates depositing a plating metal. This is so probably because an ester group generated when the resin is oxidized by ultraviolet irradiation is converted into a more hydrophilic group such as a carboxyl group by the alkali processing, and this further facilitates adsorbing catalyst ions.

Also, roughness, i.e., projections and recesses on the resin product surface increases when the alkali processing is performed after the irradiation step. This is so perhaps because the surface layer embrittled by ultraviolet irradiation is removed by the alkali processing. Therefore, the catalyst readily remains in the ultraviolet-irradiated portion, and this facilitates selectively depositing a plating metal on the ultraviolet-irradiated portion. In practice, the alkali processing facilitated depositing an electroless plating metal compared to a case in which the alkali processing step was omitted.

In one embodiment, the alkali processing is performed by processing the resin product with an alkali solution. More specifically, the alkali processing can be performed by dipping the resin product in the alkali solution. The alkali solution is not particularly limited, and an example is an aqueous sodium hydroxide solution. The time of the alkali processing is not particularly limited, and can be, for example, 1 (inclusive) to 10 (inclusive) min. The temperature of the alkali solution during the alkali processing is not particularly limited, and can be, for example, 20° C. (inclusive) to 100° C. (inclusive).

By thus performing the alkali processing on the whole resin product, the operation of the alkali processing can be simplified. In this case, the material of the resin product is selected so as not to deposit a plating metal on a portion not irradiated with ultraviolet light. For example, a resin product having an alkali resistance can be selected. More specifically, a resin material which is not modified by the alkali processing or is modified by the alkali processing to some extent but does not allow the deposition of a plating metal is selected. An example of the resin which is not modified by the alkali processing is a resin such as a cycloolefin polymer material or polystyrene material in which the polymer skeleton is formed by carbon atoms. An example of the resin which is modified to some extent but does not allow the deposition of a plating metal is a polyethylene terephthalate material (PET). On the other hand, an example of the resin which is readily modified by the alkali processing to such an extent that a plating metal is deposited is a polyimide material. When performing the alkali processing on the resin like this, it is possible to selectively perform the alkali processing on a portion of the resin product, for example, a portion irradiated with ultraviolet light.

(Application Step)

The application step is performed after the irradiation step or alkali processing step. In the application step, an electroless plating catalyst is applied to at least a portion of the surface of the resin product, that is, a portion of the surface of the resin product, which is irradiated with ultraviolet light in the irradiation step.

More specifically, the resin product is first processed with a solution containing, as a catalyst, a palladium complex having a positive electric charge at least at a part of the palladium complex. In one embodiment, a solution containing palladium complex ions having a positive electric charge in a solution is used so as to improve adhesion to the portion modified by ultraviolet irradiation. An example of the palladium complex having a positive electric charge at least at a part of the palladium complex is a complex in which an amine-based ligand forms a coordinate bond. Another example of the palladium complex having a positive electric charge at least at a part of the palladium complex is a basic amino acid complex of palladium. In the following description, a case in which the basic amino acid complex of palladium is used as the catalyst will be explained.

First, the resin product is processed with a solution containing the basic amino acid complex of palladium. By this processing, the ultraviolet-irradiated portion of the surface of the resin product adsorbs palladium ions. After that, a palladium metal catalyst is deposited on the ultraviolet-irradiated portion of the surface of the resin product by reducing the palladium ions.

First, the step of processing the resin product with the solution containing the basic amino acid complex of palladium will be explained. The basic amino acid complex of palladium is a complex of palladium ions and basic amino acid. The palladium ions are not limited, and divalent palladium ions are often used. The basic amino acid may be natural amino acid or artificial amino acid. In one embodiment, the amino acid is α-amino acid.

An example of the basic amino acid is amino acid having a basic substituent group such as an amino group or guanidyl group on the side chain. An example of the basic amino acid is lysine, arginine, or ornithine.

In one embodiment, the basic amino acid complex of palladium is represented by formula (II):

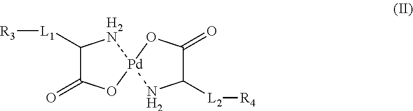

In formula (II), L₁ and L₂ each independently represent an alkylene group having 1 to 10 carbon atoms, and R₃ and R₄ each independently represent an amino group or guanidyl group. An example of the alkylene group having 1 to 10 carbon atoms is a straight-chain alkylene group such as a methylene group, 1,2-ethanediyl group, 1,3-propanediyl group, or n-butane-1,4-diyl group.

In formula (II), two amino groups are coordinated in trans-positions. However, the two amino groups may also be coordinated in cis-positions. In addition, the basic amino acid complex of palladium may also be a mixture of a cis isomer and trans isomer.

The solution containing the basic amino acid complex of palladium can be prepared by, for example, dissolving palladium salt and basic amino acid in water. In one embodiment, the pH of the solution is 3.0 (inclusive) to 9.0 (inclusive). In this pH range, it is expected that complex formation is promoted, and the complex has a positive electric charge, more specifically, a nitrogen-atom portion of the complex has a positive electric charge. Accordingly, a hydrophilic group such as a carboxyl group existing on the resin product surface readily adsorbs the complex.

In one embodiment, catalyst application is performed by dipping the resin product in a solution containing a palladium complex having a positive electric charge at least at a part of the palladium complex, for example, the basic amino acid complex of palladium. The dipping time is not particularly limited, and can be, for example, 1 (inclusive) to 10 (inclusive) min. The solution temperature during dipping is not particularly limited, and can be, for example, 20° C. (inclusive) to 100° C. (inclusive).

Next, a step of reducing palladium ions will be explained. In this step, the palladium complex having a positive electric charge at least at a part of the palladium complex, for example, the basic amino acid complex of palladium, which is applied to at least a portion of the surface of the resin product, is reduced by a reducing agent. The reducing method is not particularly limited, and a conventionally used method can be used. Examples of the reducing agent to be used are hydrogen gas, dimethylamine borane, and sodium borohydride.

In one embodiment, catalyst application is performed by dipping the resin product in a solution containing a reducing agent. The dipping time is not particularly limited, and can be, for example, 1 (inclusive) to 10 (inclusive) min. The solution temperature during dipping is not particularly limited, and can be, for example, 20° C. (inclusive) to 100° C. (inclusive).

(Plating Step)

Subsequently, electroless plating is performed on the resin product to which the catalyst is applied, thereby forming a metal film in the ultraviolet-irradiated portion of the resin product surface. A practical electroless plating method is not particularly limited. Examples of an adoptable electroless plating method are an electroless plating method using a formalin-based electroless plating bath, and an electroless plating method using hypophosphorous acid having a low deposition rate as a reducing agent. Other practical examples of the electroless plating method are electroless nickel plating, electroless copper plating, and electroless copper-nickel plating.

In another embodiment, a metal film can be formed by a high-speed electroless plating method. The high-speed electroless plating method can form a thicker plating film. In still another embodiment, a plating metal is further deposited by electroplating on a metal film formed by electroless plating. This method can form a still thicker metal film. A practical electroplating method is not particularly limited.

The thickness of the obtained metal film is not particularly limited. A metal film having an appropriate thickness is formed in accordance with the application of a resin product with a metal film to be obtained. Also, the material of the metal film is not particularly limited. An appropriate material is selected in accordance with the application of a resin product with a metal film to be obtained.

The resin product with a metal film thus obtained and including the resin product and the metal film formed on the resin product by the above-described plating method can be used in various applications. In particular, a resin product with a metal film including a resin substrate and a metal film pattern such as copper formed on the resin product by the above-described plating method is suited to be used as a circuit board by increasing the thickness of the metal film as needed. A cycloolefin polymer material with a metal film particularly has good high-frequency characteristics because a cycloolefin polymer material has a high electrical insulation and low dielectric constant, and the interface between the metal film and cycloolefin polymer material is relatively flat. Accordingly, the cycloolefin polymer material with a metal film can be used in place of a circuit board using a fluorine-resin substrate.

When applying the catalyst to the surface of the resin product by using the palladium complex having a positive electric charge at least at a part of the palladium complex, for example, the basic amino acid complex of palladium, a conditioning process of facilitating the adhesion of catalyst ions to the resin product surface by processing the resin product with a cation polymer or the like is unnecessary. Therefore, the use of the palladium complex having a positive electric charge at least at a part of the palladium complex, for example, the basic amino acid complex of palladium makes it possible to reduce the number of steps when manufacturing the resin product with a metal film.

Furthermore, when using the palladium complex having a positive electric charge at least at a part of the palladium complex, for example, the basic amino acid complex of palladium, it is possible to suppress the deposition of a plating metal on a portion not irradiated with ultraviolet light. Since the polymer used in the conditioning process has a high viscosity, the polymer easily adheres to and remains in a portion of the resin product, which is not irradiated with ultraviolet light. In the conventional technique using the conditioning process, therefore, a plating metal is presumably deposited on a portion not irradiated with ultraviolet light. On the other hand, when using the palladium complex having a positive electric charge at least at a part of the palladium complex, for example, the basic amino acid complex of palladium, the conditioning process is not essential, and this probably facilitates selectively performing plating.

### Example 1

### Substrate Processing

In Example 1, a cycloolefin polymer material (Zeonor Film ZF-16 manufactured by ZEON, film thickness=100 μm, and surface roughness=1.01 nm) as a resin material was used as a substrate for electroless plating.

First, the following processes were performed to clean the substrate surface before surface modification was performed.

1. Ultrasonic cleaning with pure water at 50° C. for 3 min
2. Dipping in an alkaline cleaning solution (containing 3.7 wt % of sodium hydroxide) at 50° C. for 3 min
3. Ultrasonic cleaning with pure water at 50° C. for 3 min

### 4. Drying

(Irradiation Step)

Then, an irradiation step of irradiating a desired portion of the substrate with ultraviolet light was performed. In this step, the ultraviolet light was emitted in the atmosphere by using the ultraviolet irradiation apparatus including ultraviolet lamps described previously with reference to FIG. 4. A metal mask having the shape shown in FIG. 5 was inserted between the ultraviolet lamps and substrate, and desired portions on the substrate, which corresponded to the openings of the metal mask, were irradiated with the ultraviolet light.

Details of the ultraviolet lamp (low-pressure mercury lamp) used in this example were as follows.

Low-pressure mercury lamp:
UV-300 (main wavelength=185 nm, 254 nm) manufactured by SAMCO
   Illumination at irradiation distance of 3.5 cm:
5.40 mW/cm² (254 nm)
1.35 mW/cm² (185 nm)

More specifically, the above-mentioned ultraviolet lamps were used to irradiate the substrate with ultraviolet light of 1.35 mW/cm² (185 nm) for 10 min at a distance of 3.5 cm from the ultraviolet lamps. In this case, the cumulative exposure amount was 1.35 mW/cm²×600 sec=810 mJ/cm².

(Alkali Processing Step)

Subsequently, alkali processing was performed on the substrate irradiated with the ultraviolet light. More specifically, an aqueous solution containing sodium hydroxide (3.7 wt %) was prepared by using an alkali processing solution used in Cu—Ni plating solution set “AISL” manufactured by JCU, and heated to 50° C., and the substrate having undergone the irradiation step was dipped in the solution for 2 min.

(Catalyst Application Step)

After that, catalyst ions were applied to the alkali-processed substrate. More specifically, an activator solution (ELFSEED ES-300 manufactured by JCU) containing a palladium complex having a positive electric charge at least at a part of the palladium complex (a palladium(II) basic amino acid complex) was heated to 50° C., and the alkali-processed substrate was dipped in the solution for 2 min (activator processing). In addition, an activation process of reducing the catalyst ions was performed on the substrate to which the catalyst ions were applied. More specifically, an accelerator solution (ELFSEED ES-400 manufactured by JCU) was heated to 35° C., and the substrate to which the catalyst was applied was dipped in the solution for 2 min (accelerator processing).

(Plating Step)

Then, electroless plating was performed on the substrate having undergone the catalyst activation. More specifically, an electroless Cu—Ni plating solution (AISL-520 manufactured by JCU) was heated to 60° C., and the substrate having undergone the catalyst activation was dipped in the solution for 5 min. A resin product with a metal film was manufactured as described above.

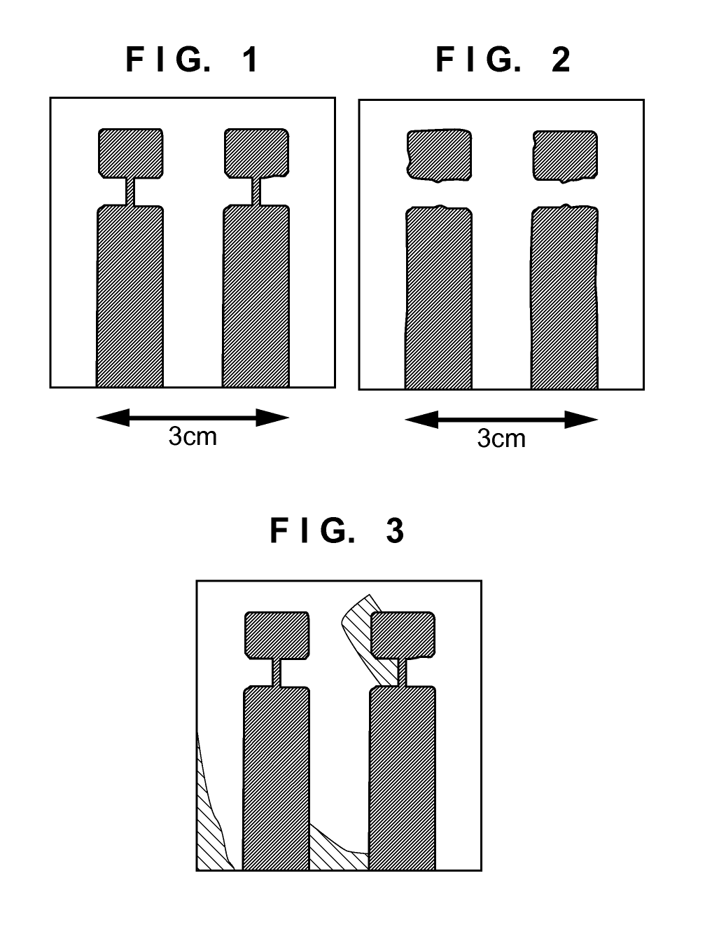

When the obtained resin product with a metal film was observed, a plating metal was deposited on a portion irradiated with the ultraviolet light, and was not deposited on a portion adjacent to the ultraviolet-irradiated portion and not irradiated with the ultraviolet light. It was thus confirmed that the plating metal was deposited without performing a conditioning process. FIG. 1 is a partially enlarged schematic view of the obtained resin product with a metal film.

### Comparative Example 1

A resin product with a metal film was manufactured following the same procedures as in Example 1 except that no alkali processing was performed. When the obtained resin product with a metal film was observed, a plating metal was deposited on most of a portion irradiated with ultraviolet light. It was thus confirmed that the plating metal was deposited without performing a conditioning process. However, no plating metal was deposited on a fine pattern portion having a small irradiation area. On the other hand, no plating metal was deposited on a portion not irradiated with the ultraviolet light. FIG. 2 is a partially enlarged schematic view of the obtained resin product with a metal film.

### Comparative Example 2

A resin product with a metal film was manufactured following the same procedures as in Example 1 except that a conditioning process was performed between alkali processing and a catalyst ion application process, and an HCl-acidic palladium solution (AISL-ACT manufactured by JCU) was used as an activator solution.

More specifically, the conditioning process was performed as follows. That is, a conditioner solution (cleaner conditioner PB-102 manufactured by JCU) containing a cation polymer was heated to 50° C., and an alkali-processed substrate was dipped in the solution for 2 min.

When the obtained resin product with a metal film was observed, a plating metal was normally deposited on a portion irradiated with ultraviolet light, but the plating metal was also partially deposited on a portion not irradiated with the ultraviolet light. FIG. 3 is a partially enlarged schematic view of the obtained resin product with a metal film.

As described above, when applying a catalyst by using a solution containing a palladium complex having a positive electric charge at least at a part of the palladium complex, for example, a basic amino acid complex of palladium, a plating metal was deposited without performing a conditioning process. It was also possible to prevent the plating metal from being deposited on a portion not irradiated with the ultraviolet light by performing no conditioning process.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2013-167027, filed Aug. 9, 2013, and No. 2014-155786, filed Jul. 31, 2014, which are hereby incorporated by reference herein in their entirety.

What is claimed is:

1. A plating method comprising:
irradiating at least a portion of a surface of a resin product with ultraviolet light;
performing alkali processing on the resin product with an alkali solution;
applying an electroless plating catalyst to the portion of the surface of the resin product which is irradiated with the ultraviolet light in the irradiating, the applying including processing the resin product with a solution containing a palladium complex having a positive electric charge at least at a part of the palladium complex; and
performing electroless plating on the resin product.

2. The method according to claim 1, wherein the palladium complex is a complex in which an amine-based ligand is bonded to a palladium ion through a coordinate bond.

3. The method according to claim 1, wherein the palladium complex is a basic amino acid complex of palladium.

4. The method according to claim 1, wherein the resin product has an alkali resistance.

5. The method according to claim 1, wherein the resin product comprises one material selected from the group consisting of a cycloolefin polymer material, a polystyrene material, and a polyethylene terephthalate material.

6. The method according to claim 1, wherein in the irradiating, the resin product is irradiated with the ultraviolet light through a mask having an ultraviolet transmitting portion corresponding to a shape of the portion of the surface of the resin product which is irradiated with the ultraviolet light.

7. The method according to claim 1, wherein the applying includes reducing, by using a reducing agent, the palladium complex applied to the surface of the resin product.

8. The method according to claim 1, wherein in the performing electroless plating, a metal film is deposited on the portion irradiated with the ultraviolet light, and is not deposited on a portion adjacent to the portion irradiated with the ultraviolet light.

9. The method according to claim 1, wherein in the irradiating, ultraviolet light having a wavelength of not more than 243 nm is emitted.

10. The method according to claim 1, wherein the irradiating is performed in an atmosphere containing at least one of oxygen or ozone.

11. A product comprising a resin product and a metal film, wherein the product is manufactured by a method comprising:
irradiating at least a portion of a surface of a resin product with ultraviolet light;
performing alkali processing on the resin product with an alkali solution;
applying an electroless plating catalyst to the portion of the surface of the resin product which is irradiated with the ultraviolet light in the irradiating, the applying including processing the resin product with a solution containing a palladium complex having a positive electric charge at least at a part of the palladium complex; and
performing electroless plating on the resin to form a metal film on the resin product.

12. The product according to claim 11, wherein the product is a circuit board.
